(19) United States
(12) Patent Application Publication
(10) Pub. No.: US 2016/0013802 A1
(43) Pub. Date: Jan. 14, 2016

(54) FREQUENCY CORRECTION SYSTEM AND CORRECTING METHOD THEREOF

(71) Applicant: SAMSUNG ELECTRO-MECHANICS CO., LTD., Suwon-si (KR)

(72) Inventors: Kyoung Joong MIN, Suwon-si (KR); Yo Sub MOON, Suwon-si (KR)

(73) Assignee: SAMSUNG ELECTRO-MECHANICS CO., LTD., Suwon-si (KR)

(21) Appl. No.: 14/750,756

(22) Filed: Jun. 25, 2015

(30) Foreign Application Priority Data
Jul. 9, 2014 (KR) 10-2014-0086166

(51) Int. Cl. H03L 7/099; H03L 7/083

(52) U.S. Cl. CPC H03L 7/0995; H03L 7/083

(57) ABSTRACT

There is provided a frequency correcting system including an oscillator outputting a target signal having an oscillating frequency, and a frequency corrector comparing the frequency of the target signal with the frequency of the reference signal and correcting the oscillating frequency to match a frequency of a predetermined reference signal, thereby automatically correcting an error in the oscillating frequency occurring during the manufacturing processes to provide precise and stable oscillating frequency.

### CROSS-REFERENCE TO RELATED APPLICATION

This application claims the benefit of Korean Patent Application No. 10-2014-0086166, filed on Jul. 9, 2014, entitled “Frequency Correction System and Correcting Method Thereof” which is hereby incorporated by reference in its entirety into this application.

### BACKGROUND

The present disclosure relates to a frequency correction system and a correcting method thereof.

Many electronic devices often require signals having frequency. For example, all digital systems require clock signals having frequency, and many analog systems require radio frequency (RF) signals, local oscillation signals, or the like. Moreover, as IT technology such as wireless mobile communications evolves recently, more precise and stable frequency is required more often.

Frequency quality of frequency oscillators for generating frequency differs depending on the fundamental circuits and material properties thereof. Due to such structural issues, the oscillators cannot always maintain the same quality, although it may slightly differ depending on the type of oscillators.

Variations in quality of oscillating frequency generated by such frequency oscillators occur, because, during the semiconductor processes, the characteristic of a transistor in an integrated circuit (IC) may be changed or errors may occur in resistance of resistors and capacitance of capacitors.

In other words, if the characteristic of a transistor of an oscillator or an integrated circuit is changed, or if the resistance of a resistor and the capacitance of a capacitor have a different value from an initially designed value, the oscillating frequency generated from the oscillator becomes different from the initially designed target frequency, and thus there exist variations.

In an integrated circuit having an oscillator, if the oscillator has large variations in oscillating frequency, it restricts the maximum frequency characteristics of the integrated circuit (IC) and applications, so that the chip performance of the integrated circuit becomes lower decreased and the yield is reduced.

Previously, if a frequency error occurs in a system sensitive to frequency due to process variations, it is necessary to correct the frequency in a separate process. In order to correct to such a frequency error, a method has been used involving measuring oscillation frequencies of frequency oscillators each in individual integrated circuits, calculating an error between the measured oscillating frequencies and the target frequency, and setting the oscillators based on the errors one by one.

### RELATED ART DOCUMENT

### Patent Document

(Patent Document 1) KR1985-0002364 A

### SUMMARY

The present disclosure is directed to comparing a frequency of a predetermined external reference signal with an oscillating frequency of a target signal to compute an error value, and then, by a main processor, correcting the oscillating frequency using a setting value corresponding to the error value. Therefore, an aspect of the present disclosure may provide a frequency correction system and a correcting method thereof that automatically correct an error in an oscillating frequency caused by various factors including process variations during the manufacturing a frequency oscillator.

According to an aspect of the present disclosure, a frequency correction system may include an oscillator outputting a target signal having an oscillating frequency, first and second counters counting the frequency of the target signal and a frequency of a predetermined reference signal, a comparator comparing first and second count values to calculate an error value, a look-up table having stored a correction value corresponding to the error value, a main processor computing a setting value, and a memory.

According to another aspect of the present disclosure, a frequency correcting method may include detecting a target signal from an oscillator, comparing an oscillating frequency of the target signal with a frequency of a reference signal and correcting a frequency of the target signal using a first error value calculated, and determining whether correction of the oscillating frequency of the target signal has been completed by comparing a second error value calculated based on the oscillating frequency of the corrected target signal and the frequency of the reference signal with a predetermined first threshold value.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a frequency correction system according to an exemplary embodiment of the present disclosure;

FIG. 2 is a diagram of a memory according to an exemplary embodiment of the present disclosure;

FIG. 3 is a flow chart for illustrating an overall frequency correcting method according to an exemplary embodiment of the present disclosure;

FIG. 4 is a flowchart for illustrating a process of selecting a correction mode and a normal mode according to an exemplary embodiment of the present disclosure;

FIG. 5 is a flow chart for illustrating a process of correcting an oscillating frequency according to an exemplary embodiment of the present disclosure;

FIG. 6 is a flow chart for illustrating a process of determining whether correction of an oscillating frequency is completed according to an exemplary embodiment of the present disclosure;

FIG. 7 is a flow chart for illustrating an oscillating frequency correcting method in a normal mode according to an exemplary embodiment of the present disclosure; and

FIG. 8 is a diagram showing timings in a correction mode according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

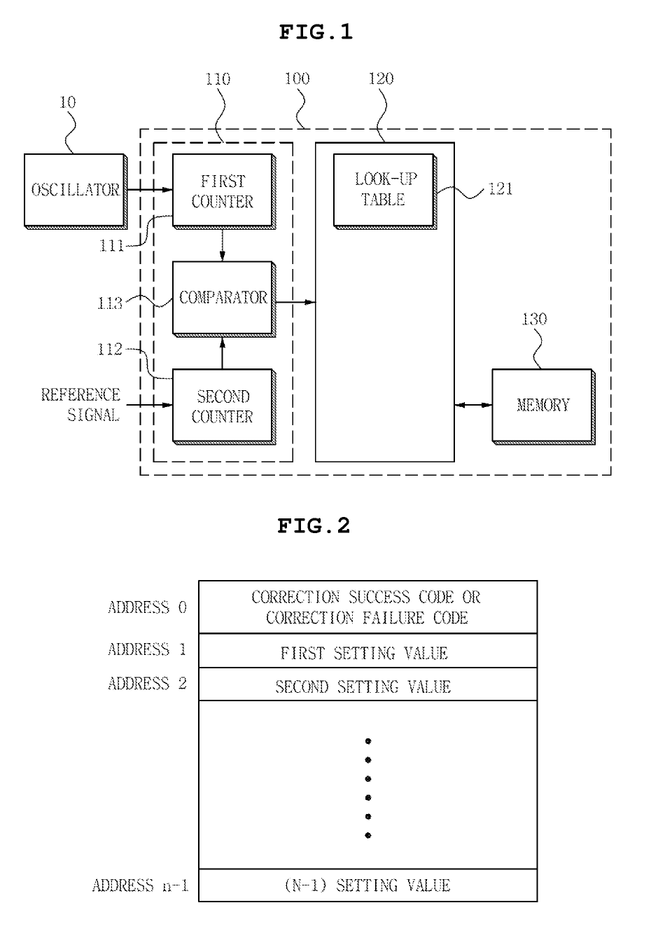

As shown in FIG. 1, a frequency correction system according to an exemplary embodiment of the present disclosure includes an oscillator 10 outputting a target signal including an oscillating frequency f1, and a frequency corrector 100 comparing the oscillating frequency f1 of the target signal with a frequency f2 of a predetermined reference signal to match the oscillating frequency f1 of the target signal to the frequency f2 of the reference signal.

The oscillator 10 is a device that generates electrical oscillation using an electron tube or a semiconductor. It is disposed inside or outside an integrated circuit to generate an oscillating frequency f1 for the use in the integrated circuit.

In addition, the oscillator 10 generates a target signal including an oscillating frequency in the form of a clock signal or converts it into a clock signal to transmit it to a first counter 111. The oscillator 10 receives a setting value of a main processor 120 and corrects the oscillating frequency f1 of the target signal according to the setting value. The oscillator 10 may be, but is not limited to, a ring oscillator composed of one or more inverters connected in series.

The frequency corrector 100 is to correct errors in the oscillating frequency f1 caused by various factors such as variations in processes of the oscillator 10. The frequency corrector 100 receives a target signal and a reference signal to calculate a setting value to control parameters of the oscillator 10 and then sends it to the oscillator 10, thereby correcting the oscillating frequency f1 of the target signal. The frequency corrector 100 includes an error calculating unit 110 comparing a frequency f2 of the reference signal with an oscillating frequency f1 of the target signal to calculate an error value, a main processor 120 computing a setting value based on the error value, and a memory 130 storing the setting value therein.

The frequency f2 of the reference signal is a target frequency at the time of designing. It is not necessarily limited to a design target but may be determined as desired by a user. The frequency f2 of the reference signal is input to a second counter 112 in the form of a clock signal. The reference signal may be input via test equipment at a test set-up stage after manufacturing an integrated circuit.

The error calculating unit 110 calculates an error value based on the frequency f2 of the reference signal with the oscillating frequency f1 of the target signal, and transmits the error value to the main processor 120. The error calculating unit 110 includes a first counter 111 counting the oscillating frequency f1 of the target signal to output a first count value, a second counter 112 counting the frequency f2 of the reference signal to output a second count value, and a comparator 113 comparing the first count value and the second count value to calculate an error value.

The counters 111 and 112 count the oscillating frequency f1 of the target signal and the frequency f2 of the reference signal to output digital values. The counters 111 and 112 store the value of 1 whenever one cycle of a signal elapses. The first counter 111 counts the oscillating frequency f1 of the target signal. The second counter 112 counts the frequency f2 of the reference signal. The first and second counters 111 and 112 send their respective count values to the comparator 113 and may be configured as hardware.

A maximum value to be compared to the second count value refers to a maximum value countable by the counters 111 and 112. For example, if the second counter 112 is of a 4-bit counter, the counting range is from 0000 to 1111, with the maximum value of 15. The time point when the second count value reaches the maximum value is the reference time point. At this time point, the first and second counters 111 and 112 stop counting and send the first and second count values to the comparator 113, respectively, for comparison of the first and second count values.

Because the oscillating frequency f1 of the target signal may possibly be higher than the frequency f2 of the reference signal, the first counter 111 has a counting range broader than the counting range of the second counter 112.

For example, if the first and second counters 111 and 112 have the same maximum value and the oscillating frequency f1 of the target signal is higher than the frequency f2 of the reference signal, the first count value reaches the maximum value before the second count value reaches the maximum value, so that comparison of the count values cannot be carried out accurately. This is because the counting operation is controlled based on the second count value and the maximum value of the second counter 112.

Namely, the maximum value of the first counter 111 is set to be larger than that of the second counter 112 in order to obtain the same period for comparison between oscillation frequencies f1 of different target signals and the frequency f2 of the reference signal. On the contrary, if the reference time point is set based on the first count value, the maximum value of the second counter has to be larger than that of the first counter.

The comparator 113 compares the first count value of the oscillating frequency f1 with the second count value of the frequency of the reference signal frequency to calculate an error value, and sends the calculated error value to the main processor 120. Additionally, the comparator 113 may be configured as either hardware or software.

For calculating the error value, the comparator 113 performs division operation using the first count value and the second count value. The error value is 1 if the oscillating frequency f1 of the target signal is equal to the frequency f2 of the reference signal. In addition, the comparator 113 may calculate the error value by performing subtraction operation using the first count value and the second count value. In this instance, the error value is zero if the oscillating frequency f1 of the target signal is equal to the frequency f2 of the reference signal.

However, the error value may be calculated by using various methods other than division operation or subtraction operation. Depending on the type of the operation, the error value may be a percentage values instead of an integer value.

The main processor 120 computes a setting value to control the oscillating frequency f1 based on the error value and corrects the oscillating frequency f1 to be matched to the frequency f2 of the reference signal. In addition, the main processor 120 includes a look-up table 121 in which correction values corresponding to error values are stored.

The look-up table 121 refers to a collection of results pre-computed for a given operation so as to save processing time since such indexing is faster than performing the given operation. In the look-up table 121, correction values corresponding to the error values calculated by the error calculation unit are stored. A correction value is selected based on an error value by the error calculating unit 110.

The main processor 120 computes a setting value based on the correction value sent from the look-up table 121 to send the setting value to the oscillator 10. The setting value is used to control parameters determining the characteristic of the oscillating frequency f1 of the target signal of the frequency oscillator 10. Upon receiving the setting value, the frequency oscillator 10 changes the parameter to generate a new oscillating frequency f1.

Therefore, according to an exemplary embodiment of the present disclosure, variations in the oscillating frequency f1 of the target signal are corrected automatically. As a result, deviations in frequency output are reduced, so that reliability of frequency in a system requiring accurate frequency is increased. Accordingly, frequency applied to an integrated circuit approximates to the maximum operating frequency of the integrated circuit to thereby improve the overall performance of the system.

As shown in FIG. 2, the memory 130 stores therein correction completion code, correction failure code and setting values. Specifically, the memory 130 stores the correction completion code at an address if a second error value is smaller than a first threshold value, and stores the correction failure code at an address if the second error value is larger than the first threshold value. If no correction has been made, no code is stored. [0034] Therefore, if the correction completion code or the correction failure code is stored, it means that the oscillating frequency f1 is corrected. Storing the correction completion code or the correction failure code is for preventing that a noise occurs in a frequency correction system so that a correction is performed again even though correction has been performed.

Setting values are stored in the boxes below the box in which the codes are stored. A setting value is stored if the second error value is smaller than the predetermined first threshold value. If a start signal is not applied so that the normal mode is performed, the main processor 120 reads out a stored setting value to send it to the oscillator 10 to thereby correct the oscillating frequency f1 of the target signal. The memory 130 may be, but is not necessarily limited to, a non-volatile memory such as an EEPROM or a flash memory.

Hereinafter, a frequency correction method according to an exemplary embodiment of the present disclosure will be described, which includes the above-described elements. In the following description, redundant descriptions of the same or similar elements will be omitted or described briefly.

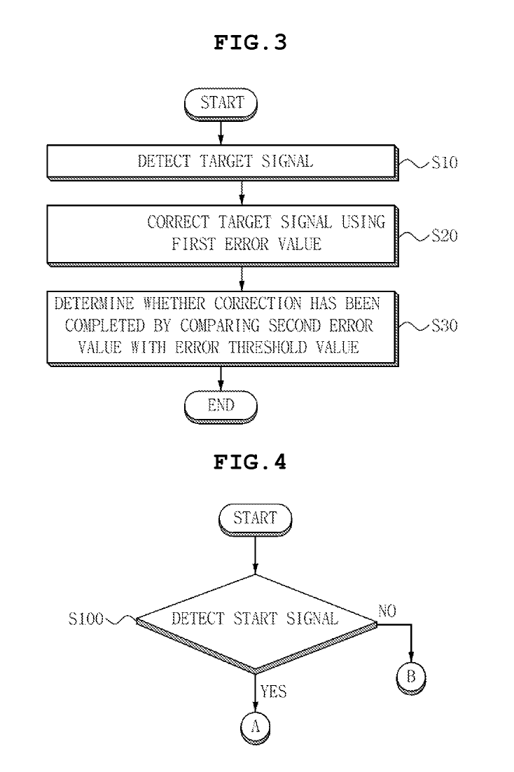

FIGS. 3 to 7 are flowcharts for illustrating a frequency correction method.

As shown in FIG. 3, the frequency correction method according to an exemplary embodiment of the present disclosure includes detecting a target signal from the oscillator 10 (S10), and comparing the oscillating frequency f1 of the target signal with the frequency f2 of the reference signal to perform a correction mode in which the frequency of the target signal is corrected to be matched to the frequency f2 of the reference signal.

The correction mode includes comparing the oscillating frequency f1 of the target signal with the frequency f2 of the reference signal and correcting the oscillating frequency f1 of the target signal using the first error value calculated (S20), and determining whether the correction of the frequency of the target signal has been completed by comparing the second error value calculated based on the corrected target signal and the frequency f2 of the reference signal with the predetermined first threshold value (S30).

FIG. 4 is a flowchart for illustrating detecting a start signal to determine a correction mode or a normal mode (S100). The correction mode is selected if the start signal is detected, whereas the normal mode is selected if the start signal is not detected. As described above, the correction mode is a method for correcting the frequency oscillator 10 by computing a setting value with the oscillating frequency f1 of the target signal and the frequency f2 of the reference signal. The normal mode is a method for correcting the oscillator 10 using the pre-stored setting values in the memory 130.

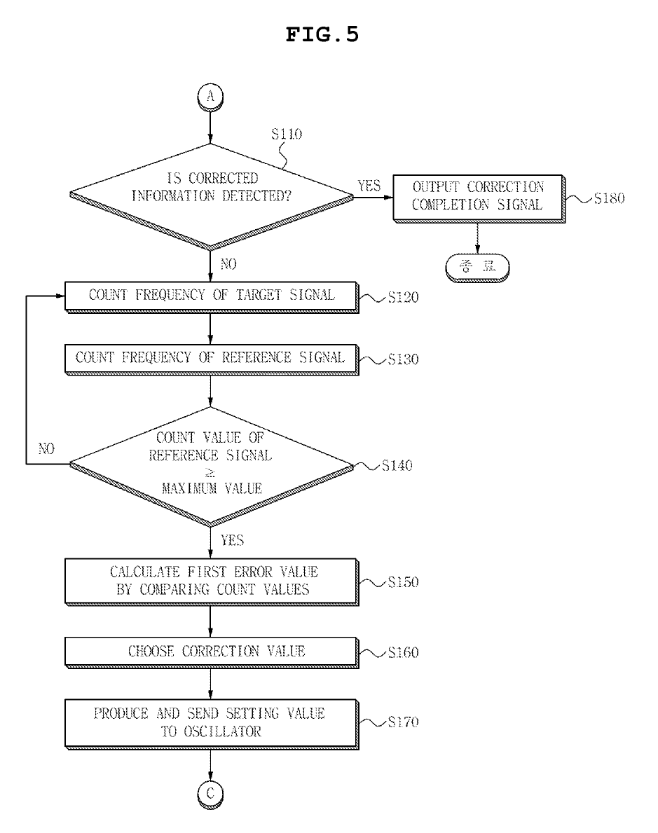

If the start signal is detected, the correction success code or the correction failure code is detected in the memory 130 (S110). If neither the correction success code nor the correction failure code is detected, the correction mode is performed in which the oscillating frequency of the target signal is corrected using the reference signal. If the correction success code or the correction failure code is detected in the memory 130, the correction completion signal is output, and the process is completed (S180). Detecting the correction success code or the correction failure code is for preventing malfunction of the frequency correction system due to noise. [0 042] As illustrated in FIG. 5, in the correction mode, the first counter 111 counts the oscillating frequency f1 of the target signal to output the first count value (S120). The second counter 112 counts the frequency f2 of the reference signal to output the second count value (S130). At the reference time point when the second count value reaches the predetermined maximum value (S140), the first and second counters 111 and 112 stop operation and the comparator 113 compares the first and second count values.

In doing so, two count values are compared to each other by performing division operation or subtraction operation to calculate the first error value (150). If the second count value does not reach the maximum value, it returns to the counting of the oscillating frequency f1 of the target signal (S120).

Subsequently, a correction value corresponding to the first error value output from the comparator 113 is selected from the look-up table 121 (S160), and a setting value to control the parameters of the oscillator 10 is computed based on the sent correction value. The computed setting value is sent to the oscillator 10 so that the oscillating frequency f1 of the target signal is corrected (S170).

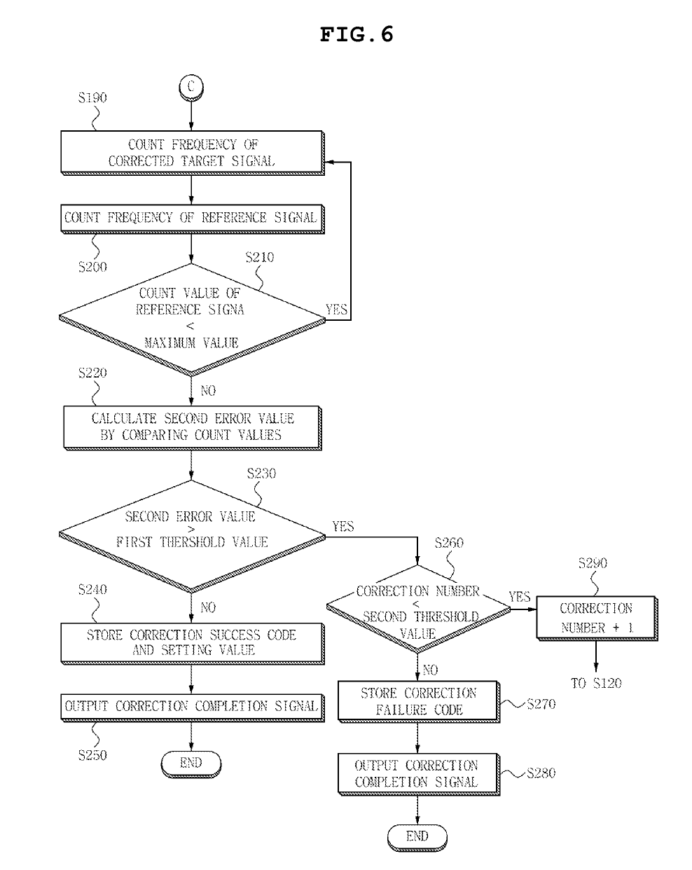

As illustrated in FIG. 6, the frequency correction method involves outputting a third count value obtained by counting the frequency of the corrected target signal and a second count value obtained by counting the frequency f2 of the reference signal (S190 and S200), determining whether the second count value has reached the maximum value, i.e., the reference time point (S210), comparing the second count value with the third count value to calculate the second error value (S220), and comparing the second error value with the predetermined first threshold value (S230). In this connection, the first threshold value is a value set by a user in order to determine whether how close the corrected oscillating frequency f1 matches the frequency f2 of the reference signal.

Accordingly, if the second error value is smaller than the first threshold value, the correction success code and the setting value are stored in the memory 130 (S240), and the correction completion signal is output (S250). On the contrary, if the second error value is larger than the first threshold value, a re-correcting is performed to retry the correction of the oscillating frequency f1 of the target signal. This is for providing precise oscillating frequency f1 by way of comparing the second error value based on the oscillating frequency f1 of the corrected target signal and the frequency f2 of the reference signal with the predetermined first threshold value to retry the correction of the oscillating frequency f1.

The re-correcting includes comparing the correction number with a predetermined second threshold value (S260). In this regard, the correction number refers to the number that the oscillating frequency f1 of the target signal is corrected, starting from zero. Additionally, the second threshold value is set in order to prevent the correction of the oscillating frequency f1 of the target signal from being repeated endlessly with the value set by a user. Accordingly, if the correction number is larger than the second threshold value, the correction failure code is stored in the memory 130 (S270), and the correction completion signal is generated (S280). If the correction number is smaller than the second threshold value, the correction number is incremented by one (S290), and it returns to the counting of the oscillating frequency f1 of the target signal (S120) to perform the correction of the oscillating frequency f1 again.

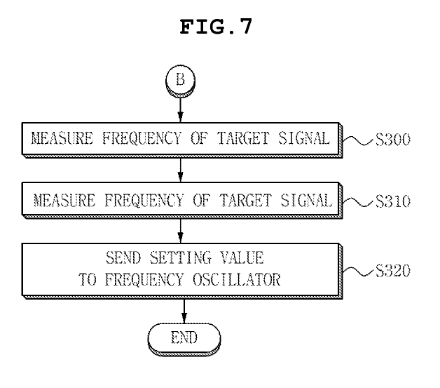

As shown in FIG. 7, the normal mode is performed if the start signal is not detected after the detecting of the start signal, so that the oscillating frequency f1 of the target signal is measured (S300), and then the setting value stored in the memory 130 is detected (S310). Subsequently, the stored setting value is transmitted from the main processor 120 to the oscillator 10, so that the oscillating frequency f1 of the target signal is corrected so as to match the frequency f2 of the reference signal (S320). Therefore, even without the frequency f2 of the external reference signal, the oscillating frequency f1 of the target signal can be corrected by using the stored setting value.

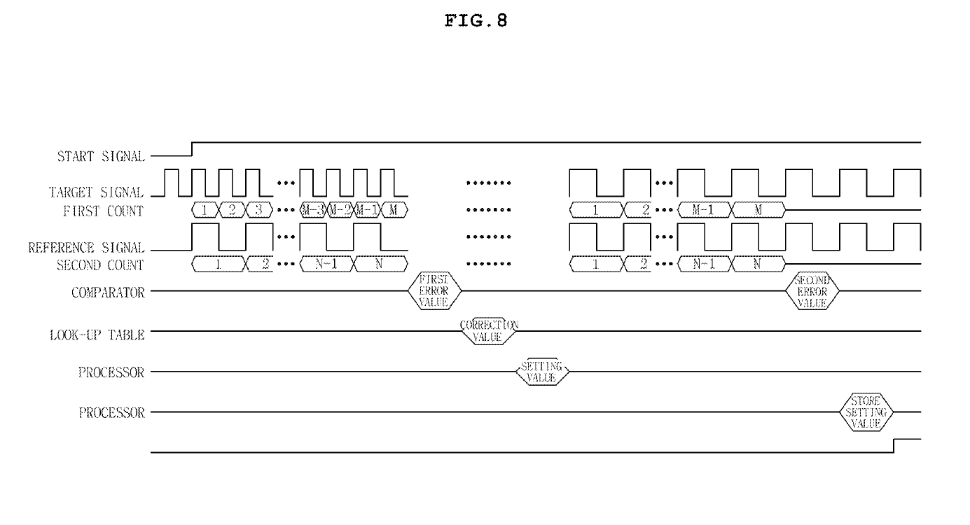

FIG. 8 is a diagram showing timings in the correction mode. Upon applying a start signal, the oscillating frequency f1 of the target signal is measured, and the first counter 111 counts the oscillating frequency f1 of the target signal. The reference signal is input simultaneously with this, the second counter 112 counts the frequency f2 of the reference signal. When the second counter 112 reaches the reference time point, the comparator 113 calculates the first error value, and then a correction value is selected from the look-up table 121. Subsequently, the main processor 120 computes a setting value to correct the oscillating frequency f1. Then, the oscillating frequency f1 of the corrected target signal and the frequency f2 of the reference signal are counted. After comparing two count values to calculate the second error value, the setting value is stored in the memory 130 if the second error value is smaller than the predetermined first threshold value, and an end signal is output.

According to an exemplary embodiment of the present disclosure, errors in the oscillating frequency f1 of the target signal caused by variations in processes are corrected automatically. Therefore, a process of measuring the oscillating frequency f1 of the target signal for an individual integrated circuit to calculate a correction coefficient and store it can be eliminated. As a result, the correction processes become simpler and thus it takes less time to perform the correction processes. Additionally, variations in an operation frequency of an integrated circuit become smaller, so the yield of the integrated circuit is improved. As a result, reliability of the oscillator 10 is also improved.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A frequency correction system, comprising:
an oscillator outputting a target signal having an oscillating frequency; and
a frequency corrector comparing a frequency of the target signal with a frequency of a predetermined reference signal and correcting the oscillating frequency to match the frequency of the reference signal.

2. The frequency correction system of claim 1, wherein the frequency corrector includes:
an error calculating unit calculating an error value by comparing the frequency of the reference signal with the oscillating frequency of the target signal; and
a main processor computing a setting value to control the oscillator based on the error value to correct the oscillating frequency.

3. The frequency correction system of claim 2, wherein the error calculating unit includes:
a first counter counting the oscillating frequency of the target signal to output a first count value;
a second counter counting the frequency of the reference signal to output a second count value; and
a comparator comparing the first count value and the second count value to calculate the error value at a predetermined reference time point.

4. The frequency correction system of claim 3, wherein each of the first and second counters includes at least one flip-flop.

5. The frequency correction system of claim 3, wherein the reference time point is a time point when the second count value reaches a predetermined maximum value.

6. The frequency correction system of claim 2, wherein the main processor includes a look-up table having stored therein a correction value corresponding to the error value.

7. The frequency correction system of claim 1, wherein the frequency corrector includes a memory in which correction completion code, correction failure code and a setting value are stored.

8. The s frequency correction system of claim 1, wherein the oscillator is a ring oscillator.

9. A frequency correcting method, comprising:
detecting a target signal from an oscillator; and
comparing an oscillating frequency of the target signal with a frequency of a predetermined reference signal and correcting the oscillating frequency of the target signal to match the frequency of the reference signal.

10. The frequency correcting method of claim 9, wherein the correcting includes:
correcting the oscillating frequency of the target signal using a first error value calculated by comparing the oscillating frequency of the target signal with the frequency of the reference signal; and
determining whether correction of the oscillating frequency of the target signal has been completed by comparing a second error value calculated based on the oscillating frequency of the corrected target signal and the frequency of the reference signal with a predetermined first threshold value.

11. The frequency correcting method of claim 10, wherein the correcting of the oscillation frequency of the target signal includes:
outputting a first count value indicative of the counted number of the oscillation frequency of the target signal and a second count value indicative of the counted number of the frequency of the reference signal;
calculating the first error value by comparing the first count value with the second count value at a predetermined reference time point; and
selecting, from a look-up table, a correction value corresponding to the first error value, to correct the oscillation frequency of the target signal using a setting value computed based on the correction value.

12. The frequency correcting method of claim 11, wherein the reference time point is a time point when the second count value reaches a predetermined maximum value.

13. The frequency correcting method of claim 10, wherein the determining includes:
outputting a third count value indicative of the counted number of the oscillating frequency of the corrected target signal and a second count value indicative of the counted number of the frequency of the reference signal;
calculating the second error value by comparing the second count value with the third count value at a predetermined reference time point;
comparing the second error value with the first threshold value to determine whether the second error value exceeds the first threshold value;
if the second error value is smaller than the first threshold value, storing correction success code and a setting value in a memory to generate a correction completion signal; and
if the second error value is larger than the first threshold value, retrying correction of the frequency of the target signal.

14. The frequency correcting method of claim 13, wherein the retrying of the correction includes
comparing a correction number with a predetermined second threshold value;
if the correction number is smaller than the second threshold value, incrementing the correction number by one, to perform the correcting of the oscillating frequency of the target signal; and
if the correction number is larger than the second threshold value, storing correction failure code in the memory to generate the correction completion signal.

15. The frequency correcting method of claim 9, comprising: prior to the correcting,
detecting a start signal to determine a correction mode and a normal mode;
if the start signal is detected, detecting a pre-corrected information containing a correction success code and correction failure code from a memory; and
if the start signal is not detected, performing correction using a setting value pre-stored in the memory.

16. The frequency correcting method of claim 15, wherein the detecting of the information includes:
if the information is detected, generating a correction completion signal; and
if the information is not detected, performing the correction mode to correct the oscillating frequency of the target signal using the reference signal.

17. The frequency correcting method of claim 15, wherein the performing of the correction includes:
detecting the setting value pre-stored in the memory; and
sending the pre-stored setting value to the oscillator to correct the oscillating frequency of the target signal.
